(19) United States
(12) Patent Application Publication
(10) Pub. No.: US 2007/0090381 A1
(43) Pub. Date: Apr. 26, 2007

(54) Semiconductor light emitting device

(75) Inventors: Kazuaki Otsuka, Kanagawa-ken (JP); Kenji Shimomura, Kanagawa-ken (JP); Hatsuo Takezawa, Kanagawa-ken (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: Kabushiki Kaisha Toshiba, Minato-ku (JP)

(21) Appl. No.: 11/494,795

(22) Filed: Jul. 28, 2006

(30) Foreign Application Priority Data
Jul. 29, 2005 (JP) 2005-220549

(51) Int. Cl. H01L 33/00; H01L 29/24

(52) U.S. Cl. 257/98; 257/100

(57) ABSTRACT

A semiconductor light emitting device comprises: a semiconductor light emitting element that emits first wavelength light; a first fluorescent material that absorbs the first wavelength light and emits second wavelength light having a longer wavelength than the first wavelength light; and a second fluorescent material that absorbs the first wavelength light and emits third wavelength light having a longer wavelength than the second wavelength light. The first fluorescent material and the second fluorescent material are represented by a common chemical composition formula. The first wavelength light, the second wavelength light, and the third wavelength light are combined into light emission of mixed color.

### CROSS-REFERENCE TO RELATED APPLICATIONS

This application is based upon and claims the benefit of priority from the prior Japanese Patent Application No. 2005-220549, filed on Jul. 29, 2005; the entire contents of which are incorporated herein by reference.

### BACKGROUND OF THE INVENTION

In recent years, semiconductor light emitting devices have been widely used in light sources for illumination and display devices. In particular, the realization of blue light emitting elements (blue LED) using gallium nitride (GaN) based materials has dramatically extended the application of white light emitting devices.

A semiconductor light emitting device for white light emission is composed of a gallium nitride based light emitting element having a wavelength range of ultraviolet to blue and fluorescent material that can be excited by absorbing the emitted light to emit light having longer wavelengths. For example, light emission from a blue light emitting element is mixed at a predefined ratio with yellow light from yellow fluorescent material that convert blue light into yellow to produce white light. In this case, silicate fluorescent material (Me_{1-y}Eu_{y})₂SiO₄ (where Me is at least one metallic element selected from Ba, Sr, Ca, and Mg) is an example yellow fluorescent material.

This configuration has a poor red color rendition because of the small amount of red components. However, in illumination and other applications, “warm colors” or “light bulb colors” are preferred. For this reason, in a previous publication (JP 2005-112922A), oxynitride red fluorescent material are used to improve red color rendition. However, the composition of oxynitride fluorescent material is physically and chemically different from that of yellow fluorescent material. As a result, the two kinds of fluorescent materials are difficult to uniformly disperse in a sealing resin, which causes a chromaticity variation or “mottling” in mass-produced products. Moreover, the reproducibility of the manufacturing process is insufficient. Consequently, the obtained characteristics are insufficient for use in light sources for illumination and display devices.

### SUMMARY OF THE INVENTION

According to an aspect of the invention, there is provided a semiconductor light emitting device comprising: a semiconductor light emitting element that emits first wavelength light; a first fluorescent material that absorbs the first wavelength light and emits second wavelength light having a longer wavelength than the first wavelength light; and a second fluorescent material that absorbs the first wavelength light and emits third wavelength light having a longer wavelength than the second wavelength light, the first fluorescent material and the second fluorescent material being represented by a common chemical composition formula, and the first wavelength light, the second wavelength light, and the third wavelength light being combined into light emission of mixed color.

According to an aspect of the invention, there is provided a semiconductor light emitting device comprising: a semiconductor light emitting element that has a light emitting layer composed of InₓGa_{y}Al_{1-x-y}N (0≦x≦1, 0≦y≦1, x+y≦1) and emits first wavelength light; a first fluorescent material that absorbs the first wavelength light and emits the second wavelength light having a longer wavelength than the first wavelength light; and a second fluorescent material that absorbs the first wavelength light and emits third wavelength light having a longer wavelength than the second wavelength light, both the first fluorescent material and the second fluorescent material being represented by a common chemical composition formula, (Me_{1-y}Eu_{y})₂SiO₄ (Me is at least one element selected from Ba, Sr, Ca and Mg, 0<y≦1), and the composition ratio y of the first fluorescent material being different from the composition ratio y of the second fluorescent material.

According to an aspect of the invention, there is provided a semiconductor light emitting device comprising: a semiconductor light emitting element that emits first wavelength light; a first fluorescent material that absorbs the first wavelength light and emits second wavelength light having a longer wavelength than the first wavelength light; a second fluorescent material that absorbs the first wavelength light and emits third wavelength light having a longer wavelength than the second wavelength light; and a third fluorescent material that absorbs the first wavelength light and emits fourth wavelength light having a longer wavelength than the third wavelength light, the first fluorescent material, the second fluorescent material and the third fluorescent material being represented by a common chemical composition formula, and the first wavelength light, the second wavelength light, the third wavelength light and the fourth wavelength light being combined into light emission of mixed color.

### BRIEF DESCRIPTION OF THE DRAWINGS

FIG. 1 is a schematic cross section showing a semiconductor light emitting device according to a first example of the invention;

FIG. 2 is a graph showing the excitation spectrum of the yellow fluorescent material according to the example of the invention;

FIG. 3 is a graph showing the emission spectrum of the semiconductor light emitting device according to the example of the invention in contrast to the emission spectrum of a first comparative example;

FIG. 4 is a chromaticity diagram of the semiconductor light emitting device according to the first example of the invention;

FIG. 5 is a chromaticity diagram of a second comparative example;

FIG. 6 is a chromaticity diagram showing a chromaticity variation distribution in the products of the first example;

FIG. 7 is a chromaticity diagram showing a chromaticity variation distribution in the second comparative example.

FIG. 8 is a photograph showing the first example as contrasted with the second comparative example in relation to the sedimentation factor in a liquid sealing resin;

FIG. 9 is a graph showing the characteristic of on-axis luminous intensity versus forward current of the semiconductor light emitting device according to the first example of the invention;

FIG. 10A is a graph showing the directional characteristics in the vertical plane of the semiconductor light emitting device according to the first example of the invention, and FIG. 10B is a schematic plan view showing the cross section for measuring the directional characteristics;

FIG. 11 is a chromaticity diagram of a semiconductor light emitting device according to a second example of the invention;

FIG. 12 is a chromaticity diagram of a semiconductor light emitting device according to a third example of the invention;

FIG. 13 is a chromaticity diagram of a semiconductor light emitting device according to a fourth example of the invention;

FIG. 14 is a graph showing the emission spectrum of the semiconductor light emitting device according to the fourth example;

FIG. 15 is a chromaticity diagram showing a chromaticity variation distribution in the products of the fourth example;

FIG. 16 is a chromaticity diagram of a semiconductor light emitting device according to a fifth example of the invention;

FIG. 17 is a graph showing the emission spectrum of the semiconductor light emitting device according to the fifth example of the invention and

FIG. 18 is a chromaticity diagram showing a chromaticity variation distribution in the products of the fifth example.

### DETAILED DESCRIPTION OF THE INVENTION

The embodiment of the invention will now be described with reference to the drawings.

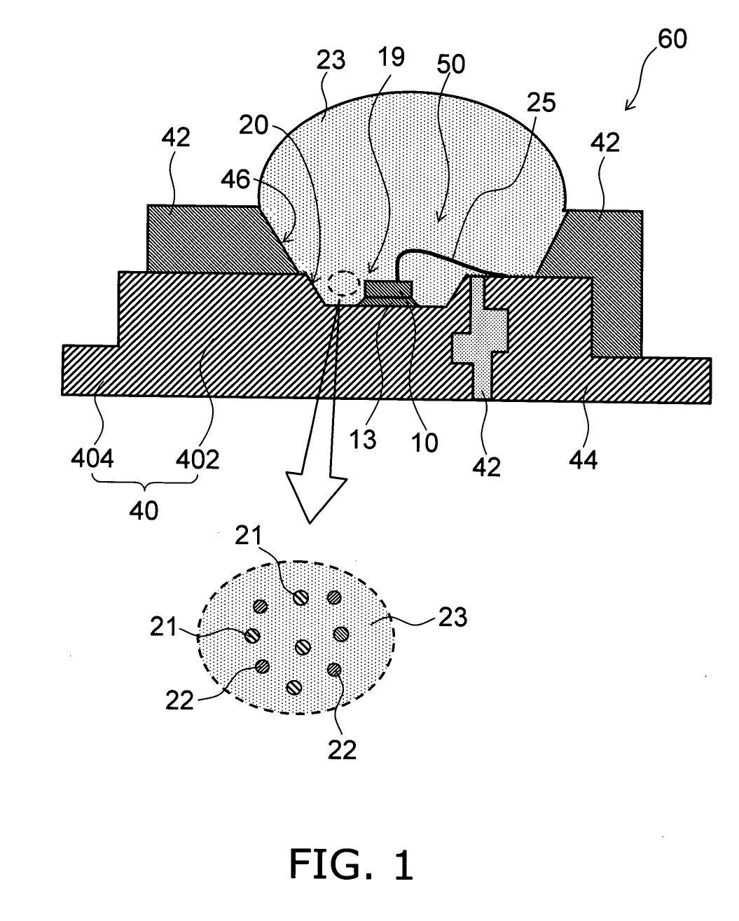

FIG. 1 is a schematic cross section showing a semiconductor light emitting device 60 according to a first example of the invention.

The semiconductor light emitting device 60 is configured so that a blue semiconductor light emitting element 10 is bonded with silver paste 13 or the like onto a thick inner lead 402 constituting a first lead 40. The inner lead 402 has a first recess 19, and the semiconductor light emitting element 10 is bonded to the bottom face of the first recess 19.

An electrode (not shown) provided on the upper face of the semiconductor light emitting element 10 is connected to a second lead 44 via a bonding wire 25. This structure is of the so-called SMD (Surface Mounting Device) semiconductor light emitting device.

The first lead 40 and the second lead 44, which are made of metal, are buried illustratively in a thermoplastic resin 42. The inner lead 402 is thicker than the outer lead 404 and serves as a heat sink for the semiconductor light emitting element 10. A second recess 50 is provided in the upper portion of the thermoplastic resin 42 so as to continue to the first recess 19. A sloping reflector 46 is provided inside the thermoplastic resin 42. The reflector 46 and the inner side face 20 of the first recess 19 serve to reflect upward the light emission from the semiconductor light emitting element 10 and wavelength-converted light from fluorescent material.

A sealing resin 23, such as silicone compounded with fluorescent material, is provided above the first recess 19 and the semiconductor light emitting element 10 provided on the inner lead 402. The sealing resin 23 shaped as a hemisphere or hemiellipsoid can serve as a lens for condensing light and facilitate controlling the directional characteristics. In this example, as illustrated by partial enlargement in FIG. 1, silicate yellow fluorescent material 21 and silicate orange fluorescent material 22 are dispersed in a transparent resin 23. As a result, light emission from the blue semiconductor light emitting element 10 is absorbed by yellow fluorescent material 21 and wavelength-converted by excitation into yellow light. On the other hand, blue light emission from the blue semiconductor light emitting element 10 is absorbed by orange fluorescent material 22 and wavelength-converted by excitation into orange light. This results in white light tinged with warm color or “light bulb color”.

Next, the fluorescent materials are described in more detail.

In this example, the yellow fluorescent material 21 and the orange fluorescent material 22 each comprise a silicate fluorescent material represented by a common chemical composition formula of (Me_{1-y}Eu_{y})₂SiO₄ (where Me is at least one element selected from Ba, Sr, Ca, and Mg, and 0<y≦1). Note that Ba (barium), Sr (strontium), and Ca (calcium) are referred to as “alkaline-earth metals”.

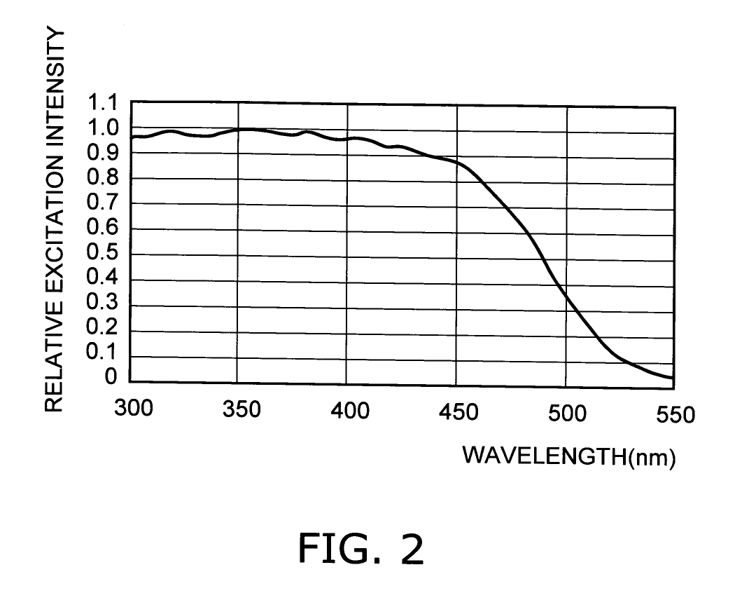

FIG. 2 is a graphical diagram showing the wavelength dependence of the excitation spectrum of the silicate yellow fluorescent material 21 used in this example.

The horizontal axis represents the wavelength (in nm) of the light source such as the semiconductor light emitting element 10, and the vertical axis represents the relative excitation intensity of the fluorescent material. In the wavelength range of 300 to 490 nanometers, light emission from the light source contributes to excitation to achieve a high excitation intensity. In this example, a blue semiconductor light emitting element 10 of 450 to 470 nanometers is used for excitation.

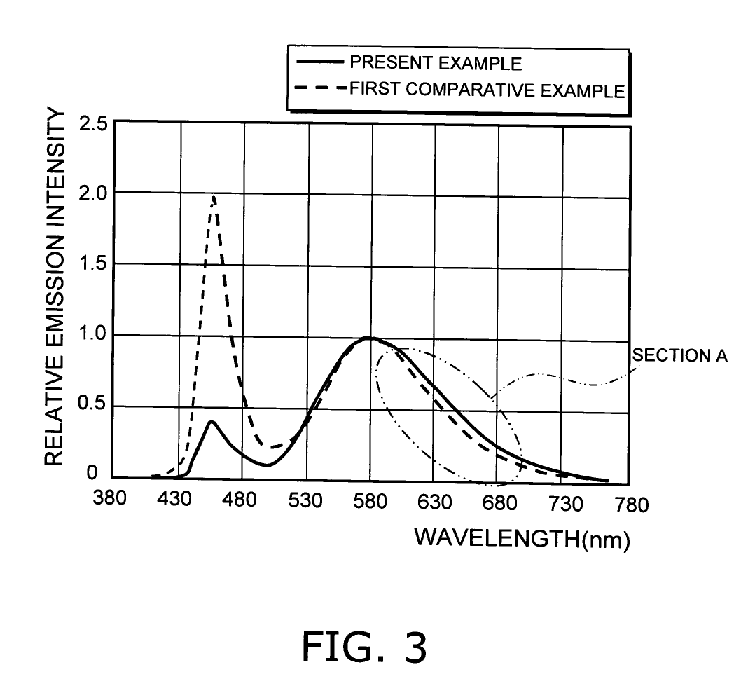

FIG. 3 is a graphical diagram showing the emission spectrum of the semiconductor light emitting device. The vertical axis represents the relative emission intensity, and the horizontal axis represents the emission wavelength (in nm).

The solid line represents the “light bulb color” of the semiconductor light emitting device 60 according to this example, which is based on three-color mixing of emission from the blue semiconductor light emitting element 10, wavelength-converted light from yellow fluorescent material 21, and wavelength-converted light from orange fluorescent material 22. The relative emission intensity has peaks approximately at 450 nanometers, where the light emission center of the blue semiconductor light emitting element 10 is located, and at 580 nanometers, where the wavelength-converted light from fluorescent material is located.

On the other hand, in a first comparative example, white light is obtained by mixing the emission of the blue semiconductor light emitting element 10 at about 450 nanometers with the yellow light from yellow fluorescent material 21. This is represented by the dashed line. The emission spectral intensity has peaks approximately at 450 nanometers, where the wavelength center of emission from the blue semiconductor light emitting element 10 is located, and at 575 nanometers, where the wavelength center of wavelength-converted light from yellow fluorescent material 21 is located. The white light of the first comparative example is obtained by mixing these two lights.

Because of orange fluorescent material 22, the emission spectrum of the present example is different from that of the first comparative example in the wavelength range above 580 nanometers. In particular, this example has a higher relative emission intensity than the first comparative example in the wavelength range (section A) of 580 to 700 nanometers illustrated by the double-dot dashed line in FIG. 3. This example achieves an improved red color rendition over the first comparative example by reinforcing this red spectral component.

It is assumed here that wavelength light from the blue semiconductor light emitting element 10 has a peak of emission spectrum in the wavelength range of 430 nanometers or more and less than 490 nanometers. It is also assumed that wavelength light emission from yellow fluorescent material has a peak of emission spectrum in the wavelength range of 490 nanometers or more and less than 580 nanometers. It is also assumed that wavelength light emission from orange fluorescent material has a peak of emission spectrum in the wavelength range of 580 nanometers or more and less than 620 nanometers.

Next, the difference in composition between the yellow fluorescent material 21 and the orange fluorescent material 22 is described, which are silicate fluorescent material represented by a common chemical composition formula of (Me_{1-y}Eu_{y})₂SiO₄ (where Me is at least one element selected from Ba, Sr, Ca, and Mg, and 0<y≦1). The material (Me_{1-y}Eu_{y})₂SiO₄ is also referred to as the matrix, and Eu (europium), which forms the emission center, is also referred to as the activator.

An example of the yellow fluorescent material 21 can be represented by the above chemical composition formula in which the composition ratio is 1.78 for Sr (strontium), 0.12 for Ba (barium), 0.10 for Eu (europium), 1.0 for Si (silicon), and 4.0 for O (oxygen).

An example of the orange fluorescent material 22 can be represented by the above chemical composition formula in which the composition ratio is 1.33 for Sr, 0.57 for Ca, 0.10 for Eu, 1.0 for Si (silicon), and 4.0 for O (oxygen). In this way, the emission spectrum can be changed by varying the composition ratio of Ba, Sr, Ca (calcium), and Mg (magnesium), generically represented by Me. Here, representation by a common chemical composition formula means the similarity of physical and chemical properties, and hence the constituent element Me does not need to be exactly the same in both materials.

Next, the particle diameter of the fluorescent material is described.

In general, there is a “fracture layer” on the surface of a fluorescent material. The thickness of the fracture layer depends on the fracture process. The volume ratio of the surface fracture layer can be reduced with the increase of the particle diameter of the fluorescent material. As a result, fluorescent material having a larger particle diameter can achieve a higher brightness. For this reason, the lower limit of the fluorescent material particle diameter is preferably about 3 micrometers.

On the other hand, the following relationship (Equation 1) approximately holds among the sedimentation velocity (v) of a fluorescent material in a liquid resin, the particle diameter (d), the fluorescent material density (ρₚ), the resin density (ρ), and the resin viscosity (η):
v=C(ρₚ−ρ)d²/η (Equation 1)
where C is a constant.

As illustratively given in Equation 1, the sedimentation velocity in the sealing resin increases as the particle diameter of the fluorescent material increases. Thus, during the assembly process, the dispersion condition of fluorescent material varies with the time period from mixing the fluorescent material into the liquid sealing resin until starting heat curing. In order to reduce this effect, the upper limit of the fluorescent material particle diameter can be illustratively set to 20 micrometers.

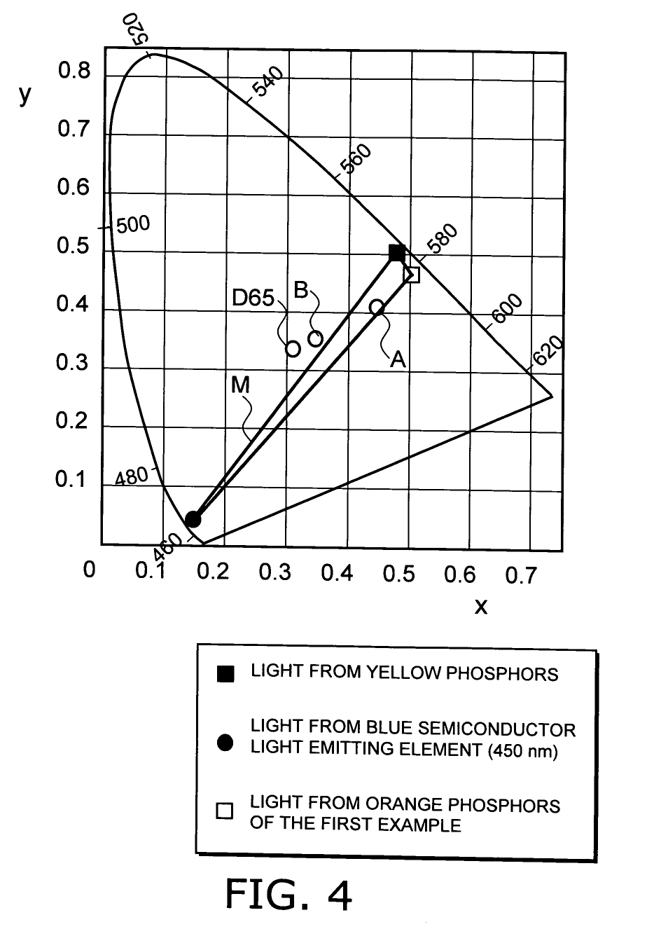

FIG. 4 is a chromaticity diagram according to the CIE (Commission Internationale de l'Eclairage) standard. The curve portion is the spectral locus for the emission wavelength of 380 to 780 nanometers, and the straight line linking both end points is the pure violet locus.

The 450-nanometer emission from the blue semiconductor light emitting element 10 is represented by xy coordinates (0.15, 0.03). The wavelength-converted light from yellow fluorescent material 21 having a peak wavelength of about 575 nanometers is represented by xy coordinates (0.480, 0.505). The wavelength-converted light from orange fluorescent material 22 having a peak wavelength of about 593 nanometers is represented by xy coordinates (0.498, 0.472). As a result, chromaticities inside the triangle linking these three points are feasible, and thus white light near the center is realized by appropriately selecting the compounding ratio. Here, A, B, and D65 represent standard lights.

Note that color mixing of the 450-nanometer emission from the blue semiconductor light emitting element 10 and the wavelength-converted light from yellow fluorescent material 21 can realize chromaticities on the straight line M linking these two points. The first comparative example is obtained in this way. Here, the white light has a poor red color rendition and lacks “warm tinge” because the red spectral component is less than that in the present example as shown by the dashed line in FIG. 3.

In contrast, in this example, the red spectral component can be reinforced by orange fluorescent material 22, and “warm tinge” can be increased. Moreover, as illustrated in FIG. 4, the flexibility of color mixing advantageously increases because of the possibility of mixing inside the triangular region in the chromaticity diagram.

Next, a second comparative example is described.

In the present example, silicate orange fluorescent material 22 are used for improving red color rendition. However, nitride fluorescent material or oxynitride fluorescent material could be used for increasing the red spectral component. Here, use of nitride fluorescent material is described as a second comparative example.

Nitride fluorescent material include Me₂Si₅N₈:Eu (Me is Sr, Ba, or Ca), CaSiN₂:Eu, and CaAl SiN₃:Eu. The second comparative example is assumed to be the case where white color is obtained by color mixing of wavelength-converted light from red fluorescent material having the chemical composition formula of Me₂Si₅N₈:Eu (Me is Sr, Ba, or Ca), 450-nanometer emission from the blue semiconductor light emitting element, and wavelength-converted light from silicate yellow fluorescent material.

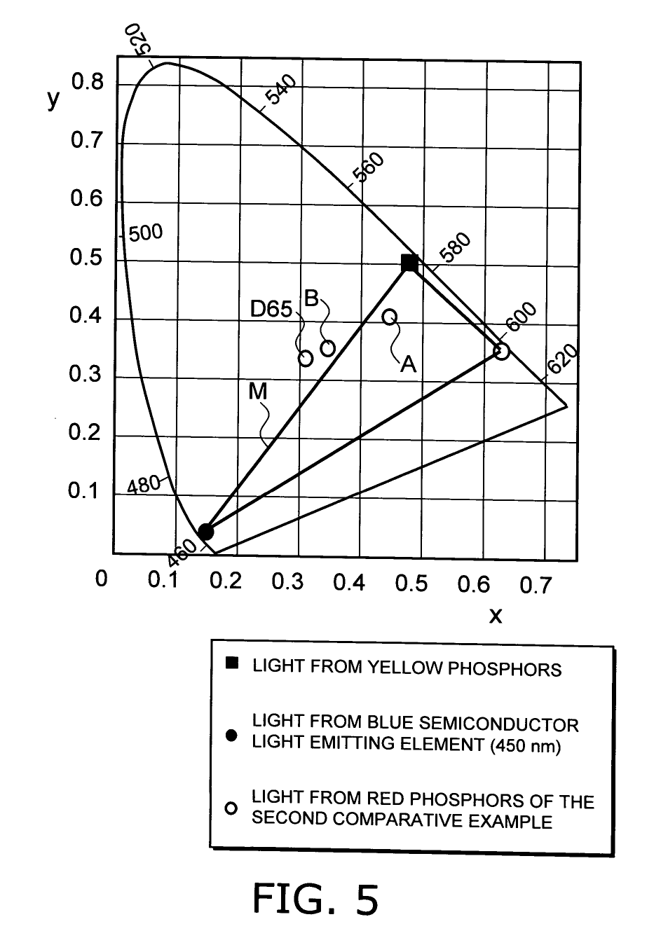

FIG. 5 is a chromaticity diagram in the second comparative example. The wavelength-converted light from red fluorescent material having a peak wavelength of about 652 nanometers is represented by xy coordinates (0.630, 0.370).

While white light is obtained by color mixing of these three colors, the chemical composition formula of the nitride or oxynitride red fluorescent material is different from that of the yellow fluorescent material. This also causes differences in physical properties such as specific weight and shape, and in chemical or other properties. As a result, these two kinds of fluorescent material are not uniformly dispersed in the sealing resin, and cause a chromaticity variation or “mottling” in manufactured products. Moreover, the reproducibility of the manufacturing process is insufficient.

Next, a comparison result is described as to the chromaticity variation or “mottling” caused by different sedimentation velocities of fluorescent material.

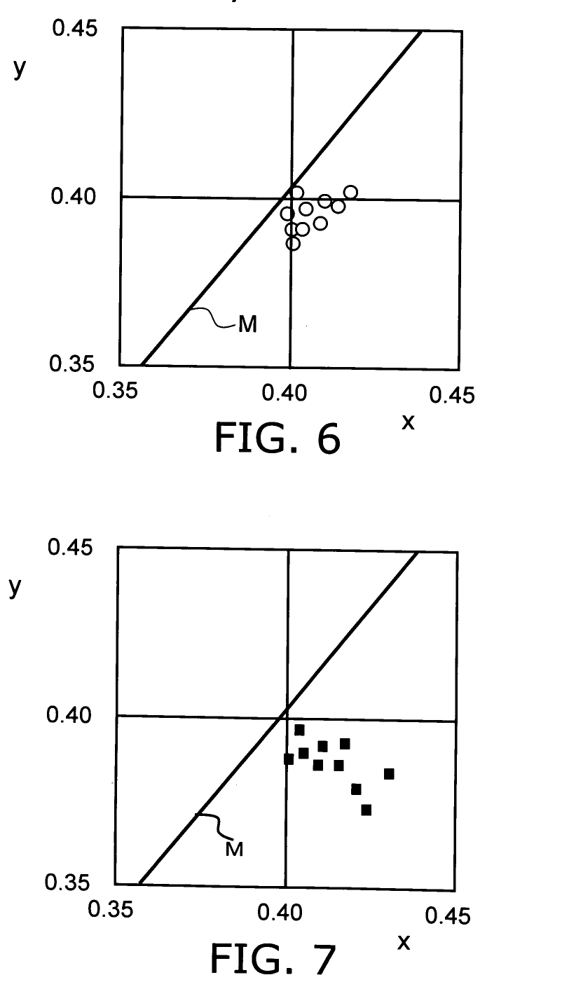

FIG. 6 shows a result of measuring the chromaticity variation distribution of the semiconductor light emitting device 60 having the structure illustrated in FIG. 1, which is made by mixing a liquid sealing resin, yellow fluorescent material 21, and orange fluorescent material 22, leaving the mixture for two hours, and then heat-curing it. FIG. 6 partially enlarges the range of coordinates x and y from 0.35 to 0.45 in the chromaticity diagram illustrated in FIG. 4. The chromaticity of 10 samples extracted from a group of products of the semiconductor light emitting device 60 is plotted as open circles. While x varies in the range of 0.398 to 0.422 and y varies in the range of 0.385 to 0.402, the chromaticity variation range of the samples is small. This presumably shows that, because of the small difference in sedimentation velocity between the yellow fluorescent material 21 and the orange fluorescent material 22, the two kinds of fluorescent material are well mixed and dispersed.

On the other hand, FIG. 7 shows a result of measuring the chromaticity variation distribution of the semiconductor light emitting device in the second comparative example, which is made by mixing a liquid sealing resin, yellow fluorescent material, and nitride red fluorescent material, leaving the mixture for two hours, and then heat-curing it. Its structure is the same as that illustrated in FIG. 1. FIG. 7 also partially enlarges the chromaticity diagram, where the chromaticity of each sample is plotted as a solid square. As illustrated in this figure, x varies in the range of 0.402 to 0.429, and y varies in the range of 0.371 to 0.395. This variation range is larger than that of the first example illustrated in FIG. 6.

The reason for this is considered as follows. In the second comparative example, because of the difference in the chemical composition formula, the yellow fluorescent material and the red fluorescent material are different in shape and specific weight, and hence are not uniformly mixed. As a result, the two kinds of fluorescent material have different sedimentation velocities, which make the sedimentation layer nonuniform.

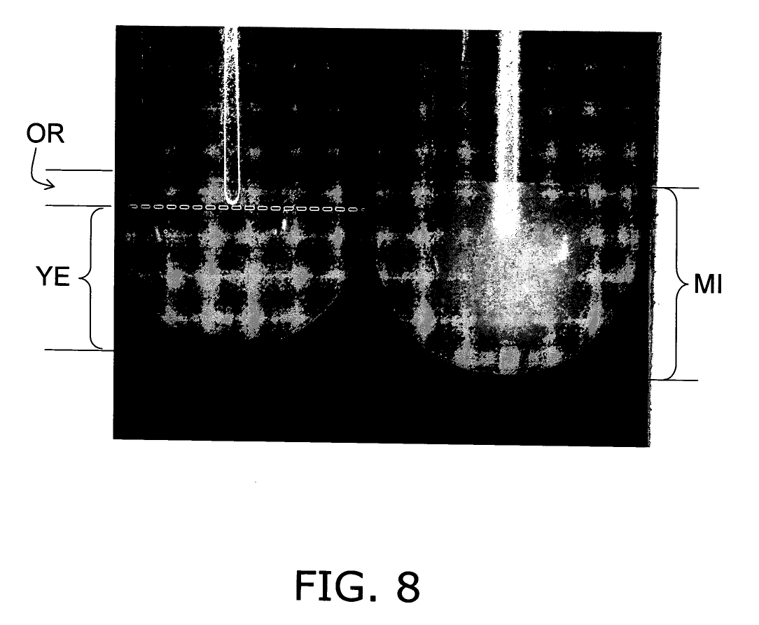

FIG. 8 is a photograph that compares the sedimentation factor of fluorescent material mixed in a liquid sealing resin and left standing for 96 hours.

The sample on the left side is of the second comparative example, where the yellow fluorescent material precipitate layer YE on the lower side and the red fluorescent material precipitate layer OR on the upper side are sedimented separately. The contrast may be obscure in FIG. 8, but to the naked eye, the red fluorescent material precipitate layer OR looks reddish, whereas the yellow fluorescent material precipitate layer YE looks yellow with little redness. In the vicinity of the boundary between them, a gradation is observed where the red component gradually decreases.

In contrast, in the sample on the right side, which is of the present example, a mixed precipitate layer MI is sedimented where the compounding ratio is nearly uniform along the depth because of the small difference in sedimentation velocity. Even to the naked eye, the overall sample looks uniform, and no unevenness of color is observed. This results in a small chromaticity variation (that is, little “mottling”), uniform characteristics, and superior reproducibility in the assembly process.

In addition, the nitride red fluorescent material in the second comparative example contains a large amount of infrared emission spectral components. This results in a decreased conversion efficiency in wavelength conversion. In contrast, in the present example, the infrared emission spectral components can be reduced. Thus the decrease of conversion efficiency can be prevented.

Next, the characteristics of the semiconductor light emitting device 60 according to this example are described.

Because the inner lead 402 is thicker than the outer lead 404, the structure illustrated in FIG. 1 has a good heat dissipation, which enables its operation at higher current.

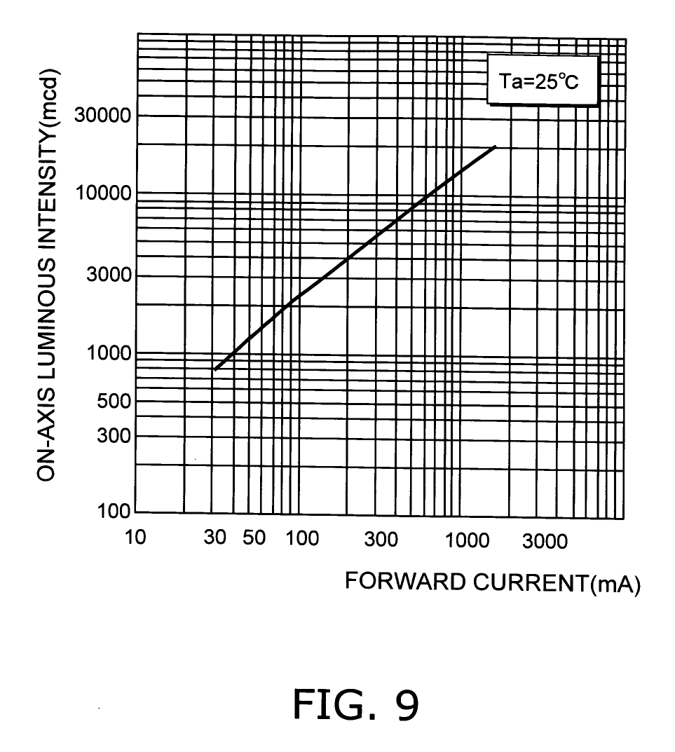

FIG. 9 shows the characteristic of on-axis luminous intensity versus forward current of the semiconductor light emitting device 60 according to this example (Ta=25° C.). At a forward current of 350 mA, an optical output of 6250 mcd is obtained. The side face 20 of the first recess 19 provided in the first lead 40 and the reflector 46 provided on the side face of the second recess 50 in the thermoplastic resin 42 effectively guide light upward. Thus the light extraction efficiency can be improved, and the directivity can be controlled.

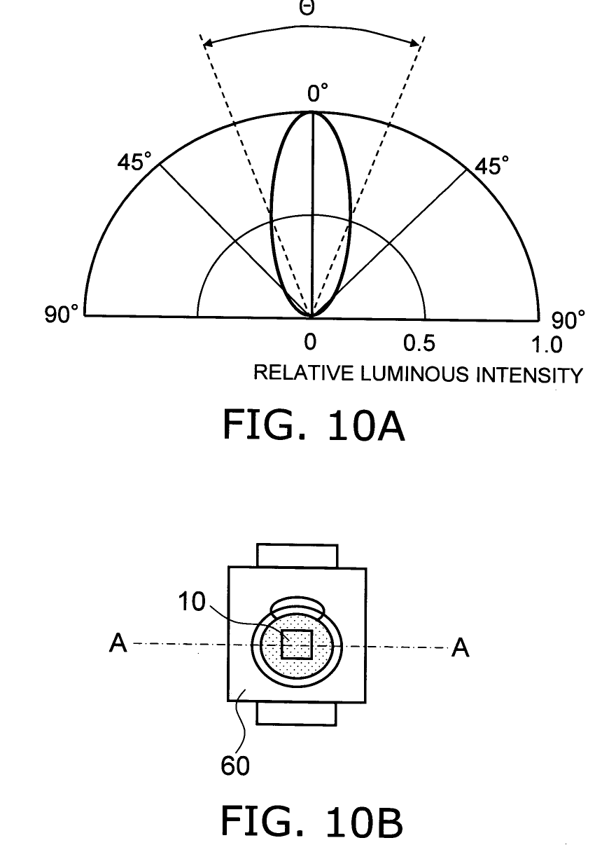

FIG. 10A is a graph showing the directional characteristics of the semiconductor light emitting device 60 according to this example. FIG. 10B is a schematic plan view of the semiconductor light emitting device 60 of this example.

In the cross section along a center line A-A′ of the semiconductor light emitting element 10 bonded in the semiconductor light emitting device 60, the directional characteristics as shown in FIG. 10A can be obtained for the measurement of the light emission intensity upward from the semiconductor light emitting element 10 with varying the angle between the measurement point and the vertical axis. The relative luminous intensity of the light emission is represented by the radial coordinate. In this configuration, the relative luminous intensity is maximized on the vertical optical axis of the semiconductor light emitting element 10, and the maximum is defined as the value “1”.

The angle at which the relative luminous intensity is half its maximum is referred to as the full angle at half maximum θ. In this example, the full angle at half maximum θ is 40 degrees, achieving a sharp directivity. This is attributed to the condensing lens function provided to the sealing resin 23 as illustrated in FIG. 1. Moreover, the full angle at half maximum θ can also be controlled by the shape and sloping angle of the side face 20 in the first recess 19 and of the reflector 46 in the second recess 50.

Such a high output and a high controllability of directional characteristics in the first example enable a semiconductor light emitting device 60 to be long-life, easy to maintain, and suitable to illumination applications. For example, its features such as small size, light weight, easy of maintenance, and long life allow a wide variety of applications in spotlights on airplanes, automobiles, and trains. Furthermore, because of the improved red color rendition, white light with “warm color” is obtained, which enhances the suitability to the above applications.

The embodiment of the invention has been described with reference to the example. However, the invention is not limited thereto. For example, emission from the semiconductor light emitting element may have a wavelength of 450 nanometers or less, illustratively including the ultraviolet region.

Furthermore, three kinds or more of fluorescent material represented by a common chemical composition formula may be contained.

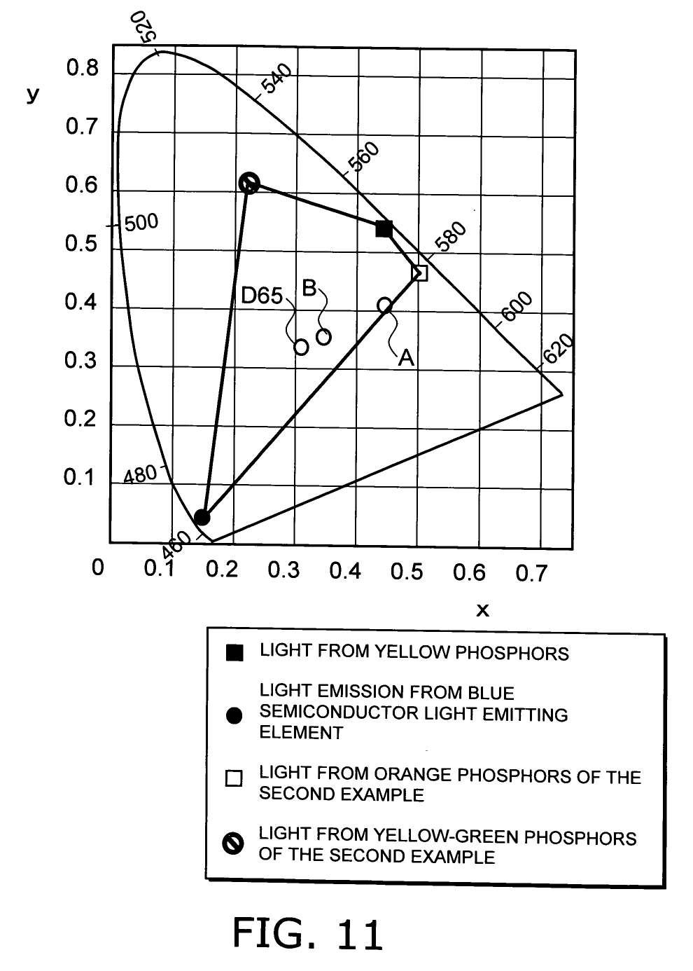

FIG. 11 is a chromaticity diagram of a semiconductor light emitting device according to a second example, which comprises three kinds of silicate fluorescent material. Emission from the blue semiconductor light emitting element is represented by xy coordinates (0.155, 0.026). Wavelength-converted light from silicate yellow fluorescent material is represented by xy coordinates (0.431, 0.545). Wavelength-converted light from silicate orange fluorescent material is represented by xy coordinates (0.498, 0.472). Finally, wavelength-converted light from silicate yellow-green fluorescent material is represented by xy coordinates (0.221, 0.615). Mixing of lights represented by these coordinates can achieve white light with richer color rendition.

Moreover, the fluorescent material are not limited to silicate fluorescent material.

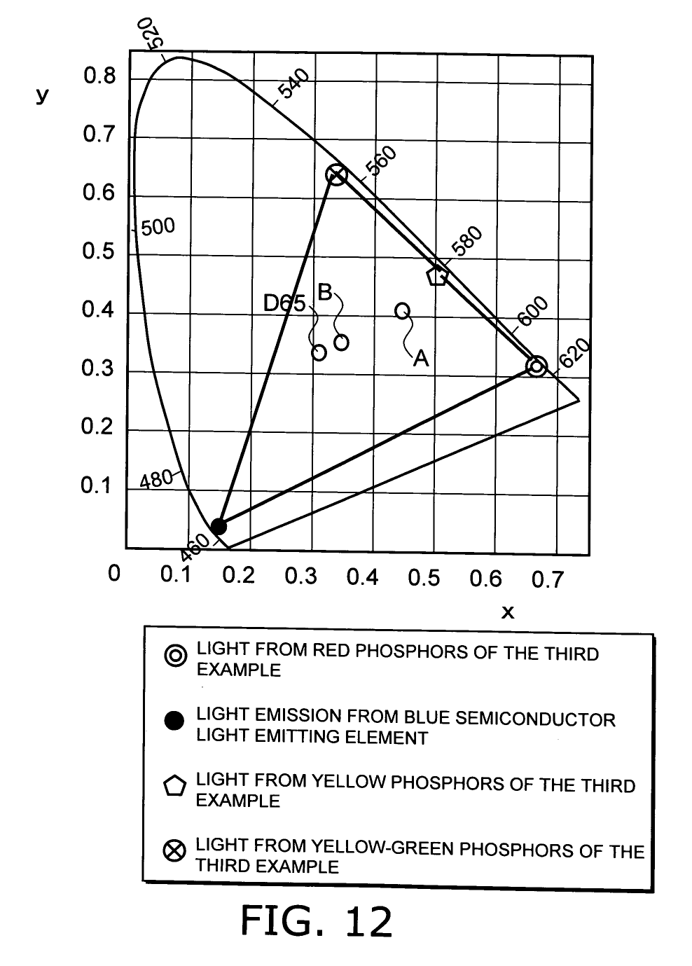

FIG. 12 is a chromaticity diagram of a semiconductor light emitting device according to a third example, which comprises three kinds of nitride fluorescent material represented by a common chemical composition formula. Emission from the blue semiconductor light emitting element is represented by xy coordinates (0.155, 0.026). Wavelength-converted light from nitride yellow fluorescent material is represented by xy coordinates (0.510, 0.480). Wavelength-converted light from nitride yellow-green fluorescent material is represented by xy coordinates (0.335, 0.640). Finally, wavelength-converted light from nitride red fluorescent material is represented by xy coordinates (0.678, 0.318). Mixing of lights represented by these coordinates can achieve white light with richer color rendition.

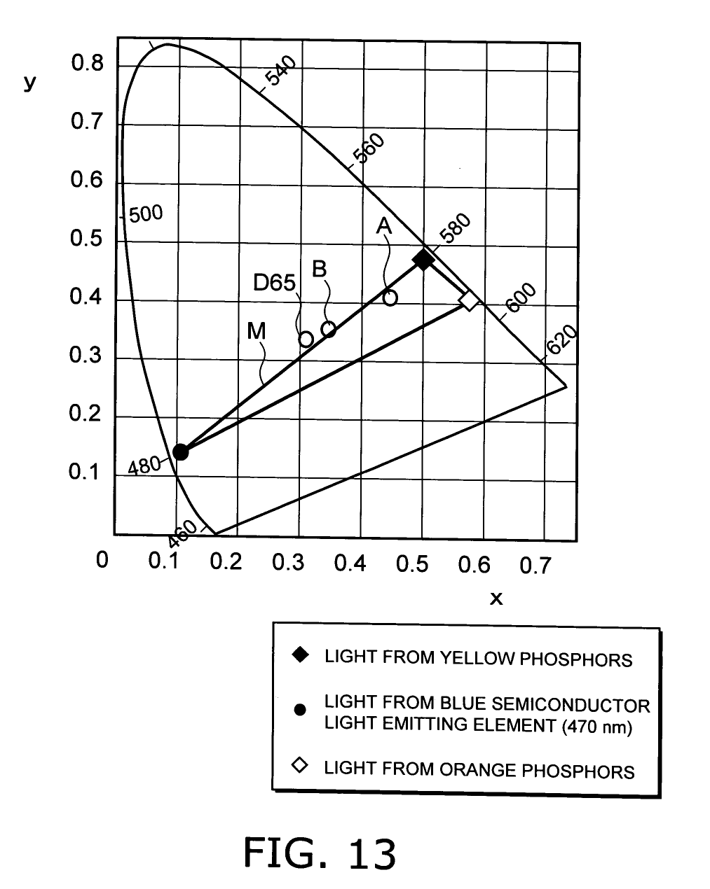

FIG. 13 is a chromaticity diagram of a semiconductor light emitting device 60 according to a fourth example of the invention, which comprises two kinds of nitride fluorescent material. The 470-nanometer emission from the blue semiconductor light emitting element 10 is represented by xy coordinates (0.100, 0.130). Here, the chemical composition formula of the nitride fluorescent material is represented by (Me_{1-z}Eu_{z})₂Si₅N₈ (0<z≦1, Me is at least one element selected from Sr, Ba, Ca and Mg). In case of a composition of the yellow fluorescent material 21 being (Ba_{0.93}Eu_{0.07})₂Si₅N₈, the peak wavelength is in the vicinity of 578 nanometers and wavelength-converted light is represented by xy coordinates (0.500, 0.480). In case of a composition of the orange fluorescent material 22 being (Ba_{0.8}Eu_{0.2})₂Si₅N₈, the peak wavelength is in the vicinity of 610 nanometers and wavelength-converted light is represented by xy coordinates (0.570, 0.405). The white light is obtained by mixing lights represented by these xy coordinates.

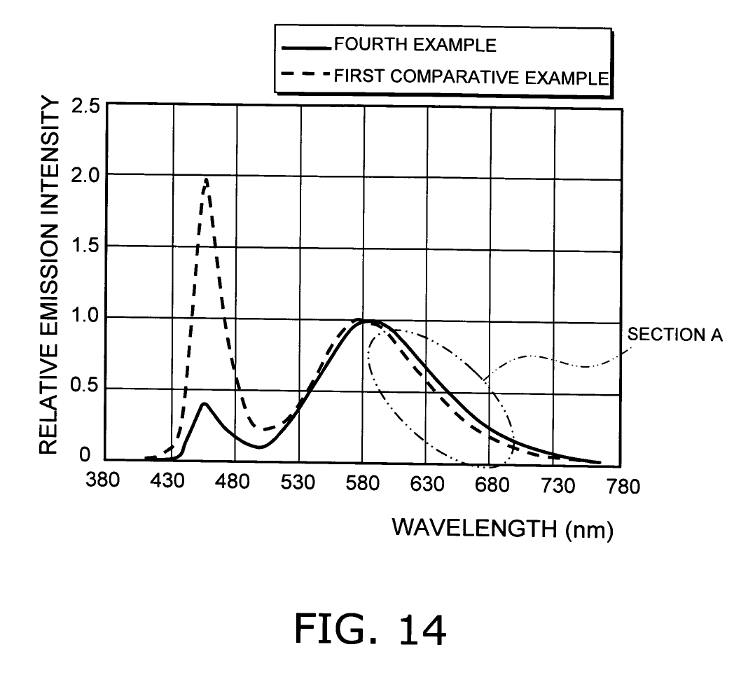

FIG. 14 is a graphical diagram showing the emission spectrum of a fourth example in comparison with the first comparative example. As indicated by a solid line, the relative emission intensity in a part of A being in the wavelength range of 580 to 700 nanometers is possible to be higher in the fourth example than the first example. The additional strength of the red spectrum intensity like this improves the red color rendition in comparison with the first example.

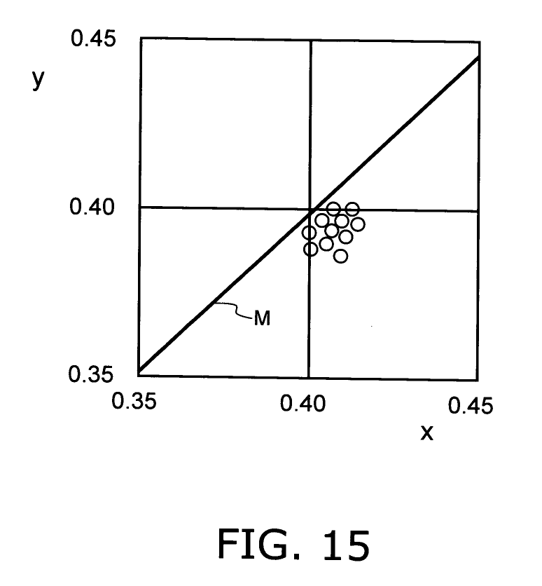

FIG. 15 is a result of measuring the chromaticity variation distribution of the semiconductor light emitting device 60, which is made by mixing yellow fluorescent material 21, orange fluorescent material 22 and liquid sealing resin, and then heat-curing it by the same process as a first example. The variation range of ten pieces of samples is smaller than that of the second example in which two kinds of fluorescent material represented by different chemical composition formulae are mixed. This presumably shows that, because of the small difference in sedimentation velocity between the yellow fluorescent material 21 and the orange fluorescent material 22, they are well mixed and dispersed.

Fluorescent material may include YAG fluorescent material represented by a chemical composition formula of (Y, Gd)₃Al₅O₁₂:Ce.

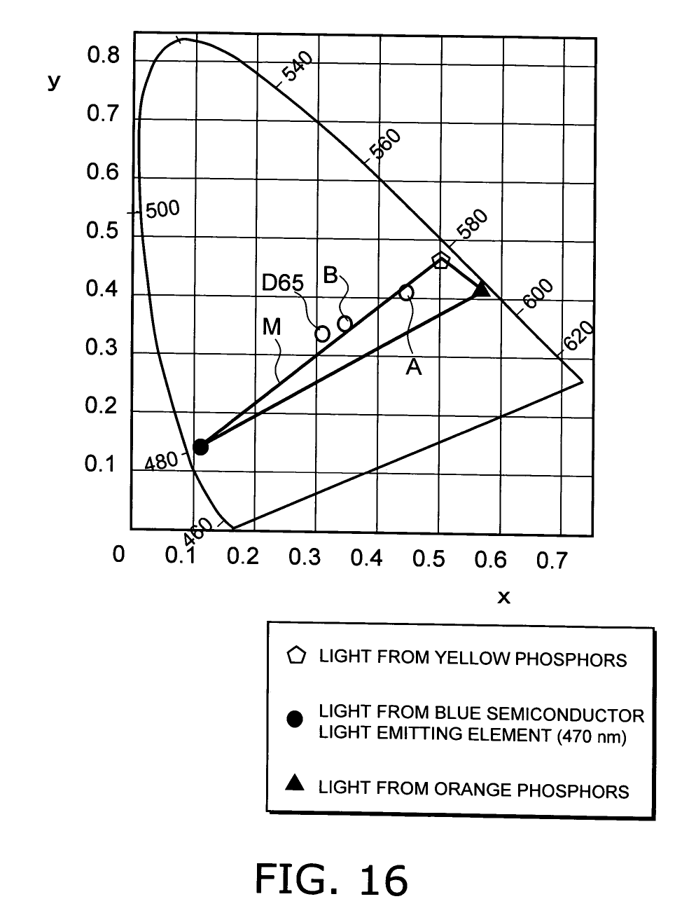

FIG. 16 is a chromaticity diagram of a semiconductor light emitting device 60 according to a fifth example of the invention, which comprises two kinds of YAG fluorescent material. The 470-nanometer emission from the blue semiconductor light emitting element 10 is represented by xy coordinates (0.100, 0.130). In case of a composition of the yellow fluorescent material 21 being (Y_{0.4}Gd_{0.6})₃Al₅O₁₂:Ce, the peak wavelength is in the vicinity of 578 nanometers and wavelength-converted light is represented by xy coordinates (0.500, 0.480). In case of a composition of the orange fluorescent material 22 being (Y_{0.2}Gd_{0.8})₃Al₅O₁₂:Ce, the peak wavelength is in the vicinity of 600 nanometers and wavelength-converted light is represented by xy coordinates (0.570, 0.410). The white light is obtained by mixing lights represented by these xy coordinates.

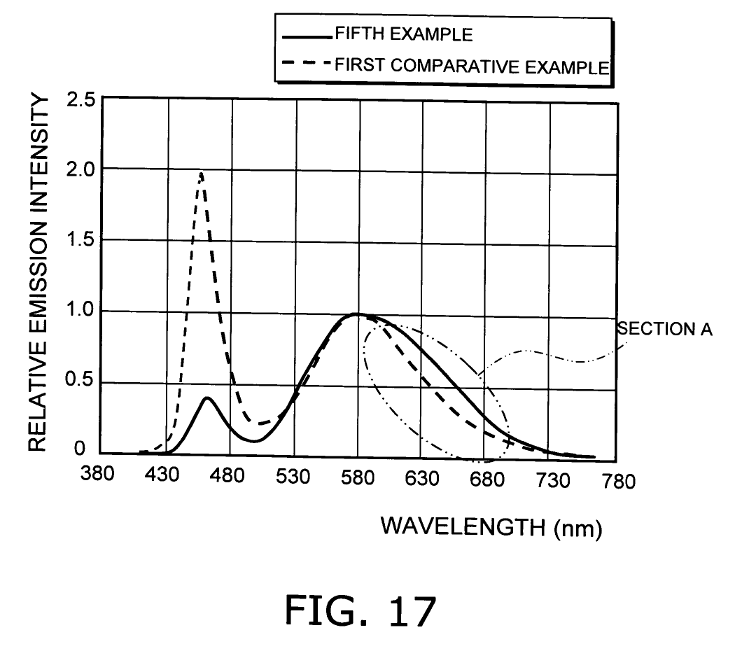

FIG. 17 is a graphical diagram showing the emission spectrum of a fifth example in comparison with the first comparative example. Use of YAG fluorescent material broadens the half width of the spectrum by about 10 nanometers to a long wavelength side. The fifth example achieves an improved red color rendition over the first comparative example.

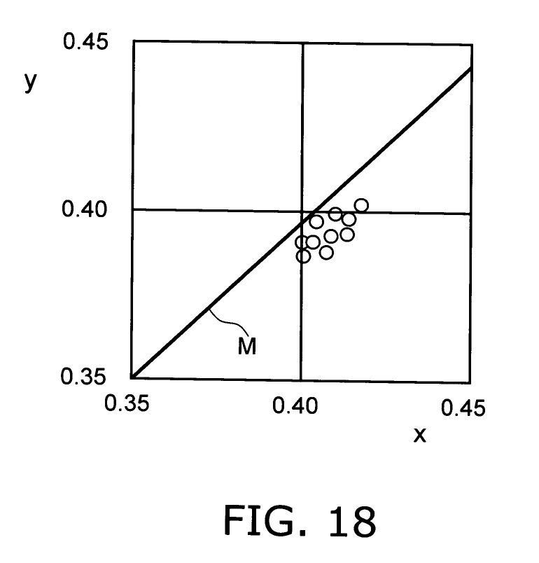

FIG. 18 is a result of measuring the chromaticity variation distribution of the semiconductor light emitting device 60. The variation range of ten pieces of samples is smaller than that of the second example. This presumably shows that the yellow fluorescent material 21 and the orange fluorescent material 22 in the resin are also well mixed and dispersed in YAG fluorescent material. In addition, the fluorescent material may be YAG fluorescent material represented by the chemical composition formula (YᵤGd₁₋ᵤ)₃(Al_{w}Ga_{1-w})₅O₁₂:Ce (0<u≦1, 0<w≦1). The shape, size, material, and positional relationship of the components constituting the semiconductor light emitting device such as the semiconductor light emitting element, leads, fluorescent material, and sealing resin that are adapted by those skilled in the art are also encompassed within the scope of the invention as long as they include the features of the invention.

1. A semiconductor light emitting device comprising:
a semiconductor light emitting element that emits first wavelength light;
a first fluorescent material that absorbs the first wavelength light and emits second wavelength light having a longer wavelength than the first wavelength light; and
a second fluorescent material that absorbs the first wavelength light and emits third wavelength light having a longer wavelength than the second wavelength light,
the first fluorescent material and the second fluorescent material being represented by a common chemical composition formula, and
the first wavelength light, the second wavelength light, and the third wavelength light being combined into light emission of mixed color.

2. A semiconductor light emitting device according to claim 1, wherein both the first fluorescent material and the second fluorescent material are silicate fluorescent material.

3. A semiconductor light emitting device according to claim 2, wherein
the first fluorescent material and the second fluorescent material are both composed of (Me_{1-y}Eu_{y})₂SiO₄ (where Me is at least one element selected from Ba, Sr, Ca, and Mg, and 0<y≦1), and
the composition ratio y of the first fluorescent material is different from the composition ratio y of the second fluorescent material.

4. A semiconductor light emitting device according to claim 3, wherein the first fluorescent material contains Sr and Ba as the element represented by Me, and the second fluorescent material contains Sr and Ba as the element represented.

5. A semiconductor light emitting device according to claim 4, wherein
the first wavelength light has a peak of emission spectrum in a wavelength range of 430 nanometers or more and less than 490 nanometers,
the second wavelength light has a peak of emission spectrum in a wavelength range of 490 nanometers or more and less than 580 nanometers, and
the third wavelength light has a peak of emission spectrum in a wavelength range of 580 nanometers or more and less than 620 nanometers.

6. A semiconductor light emitting device according to claim 1, wherein both the first fluorescent material and the second fluorescent material are nitride fluorescent material.

7. A semiconductor light emitting device according to claim 6, wherein
the semiconductor light emitting device has a light emitting layer of InₓGa_{y}Al_{1-x-y}N (0≦x≦1, 0≦y≦1, x+y≦1), and
the first fluorescent material and the second fluorescent material are both composed of (Me_{1-z}Eu_{z})₂Si₅N₈ (where Me is at least one element selected from Ba, Sr, Ca, and Mg, and 0<z≦1), and
the composition ratio z of the first fluorescent material is different from the composition ratio z of the second fluorescent material.

8. A semiconductor light emitting device according to claim 7, wherein the first fluorescent material contains Sr and Ba as the element represented by Me, and the second fluorescent material contains Sr and Ba as the element represented by Me.

9. A semiconductor light emitting device according to claim 8, wherein
the first wavelength light has a peak of emission spectrum in a wavelength range of 430 nanometers or more and less than 490 nanometers, the second wavelength light has a peak of emission spectrum in a wavelength range of 490 nanometers or more and less than 580 nanometers, and
the third wavelength light has a peak of emission spectrum in a wavelength range of 580 nanometers or more and less than 620 nanometers.

10. A semiconductor light emitting device according to claim 1, wherein both the first and the second fluorescent materials are YAG fluorescent material.

11. A semiconductor light emitting device according to claim 10, wherein
the semiconductor light emitting device has a light emitting layer of InₓGa_{y}Al_{1-x-y}N (0≦x≦1, 0≦y≦1, x+y≦1), the first fluorescent material and the second fluorescent material are both composed of (YᵤGd₁₋ᵤ)₃(Al_{w}Ga_{1-w})₅O₁₂:Ce (o<u≦1, 0<w≦1), and at least one of composition ratios u and w of the first and the second fluorescent materials are different.

12. A semiconductor light emitting device according to claim 11, wherein
the first wavelength light has a peak of emission spectrum in a wavelength range of 430 nanometers or more and less than 490 nanometers,
the second wavelength light has a peak of emission spectrum in a wavelength range of 490 nanometers or more and less than 580 nanometers, and
the third wavelength light has a peak of emission spectrum in a wavelength range of 580 nanometers or more and less than 620 nanometers.

13. A semiconductor light emitting device comprising:
a semiconductor light emitting element that has a light emitting layer composed of InₓGa_{y}Al_{1-x-y}N (0≦x≦1, 0≦y≦1, x+y≦1) and emits first wavelength light;
a first fluorescent material that absorbs the first wavelength light and emits the second wavelength light having a longer wavelength than the first wavelength light; and
a second fluorescent material that absorbs the first wavelength light and emits third wavelength light having a longer wavelength than the second wavelength light,
both the first fluorescent material and the second fluorescent material being represented by a common chemical composition formula, (Me_{1-y}Eu_{y})₂SiO₄ (Me is at least one element selected from Ba, Sr, Ca and Mg, 0<y≦1), and
the composition ratio y of the first fluorescent material being different from the composition ratio y of the second fluorescent material.

14. A semiconductor light emitting device according to claim 13, wherein the first fluorescent material contains Sr and Ba as elements represented by Me, and the second fluorescent material contains Sr and Ba as elements represented by Me.

15. A semiconductor light emitting device according to claim 13, wherein
the first wavelength light has a peak of emission spectrum in a wavelength range of 430 nanometers or more and less than 490 nanometers,
the second wavelength light has a peak of emission spectrum in a wavelength range of 490 nanometers or more and less than 580 nanometers, and
the third wavelength light has a peak of emission spectrum in a wavelength range of 580 nanometers or more and less than 620 nanometers.

16. A semiconductor light emitting device comprising:
a semiconductor light emitting element that emits first wavelength light;
a first fluorescent material that absorbs the first wavelength light and emits second wavelength light having a longer wavelength than the first wavelength light;
a second fluorescent material that absorbs the first wavelength light and emits third wavelength light having a longer wavelength than the second wavelength light; and
a third fluorescent material that absorbs the first wavelength light and emits fourth wavelength light having a longer wavelength than the third wavelength light,
the first fluorescent material, the second fluorescent material and the third fluorescent material being represented by a common chemical composition formula, and
the first wavelength light, the second wavelength light, the third wavelength light and the fourth wavelength light being combined into light emission of mixed color.

17. A semiconductor light emitting device according to claim 16, wherein
the first wavelength light has a peak of emission spectrum in the wavelength range of 430 nanometers or more and less than 490 nanometers and
the second wavelength light, the third wavelength light and the fourth wavelength light have peaks of emission spectrum in the wavelength range of 490 nanometers or more and less than 620 nanometers.

18. A semiconductor light emitting device according to claim 16, wherein
the semiconductor light emitting element has a light emitting layer of InₓGa_{y}Al_{1-x-y}N (0≦x≦1, 0≦y≦1, x+y≦1),
all of the first fluorescent material, the second fluorescent material and the third fluorescent material are (Me_{1-y}Eu_{y})₂SiO₄ (Me is at least one element selected from Ba, Sr, Ca and Mg, 0<y≦1), and
the composition ratio y of the first fluorescent material, the composition ratio y of the second fluorescent material and the composition ratio y of the third fluorescent material are different each other.

19. A semiconductor light emitting device according to claim 16, wherein
the semiconductor light emitting element has a light emitting layer of InₓGa_{y}Al_{1-x-y}N (0≦x≦1, 0≦y≦1, x+y≦1),
all of the first fluorescent material, the second fluorescent material and the third fluorescent material are (Me_{1-z}Eu_{z})₂Si₅O₄ (Me is at least one element selected from Ba, Sr, Ca and Mg, 0<z≦1), and
the composition ratio z of the first fluorescent material, the composition ratio z of the second fluorescent material and the composition ratio z of the third fluorescent material are different each other.

20. A semiconductor light emitting device according to claim 16, wherein
the semiconductor light emitting element has a light emitting layer of InₓGa_{y}Al_{1-x-y}N (0≦x≦1, 0≦y≦1, x+y≦1),
all of the first fluorescent material, the second fluorescent material and the third fluorescent material are (YᵤGd₁₋ᵤ)₃(Al_{w}Ga_{1-w})₅O₁₂:Ce (0<u≦1, 0<w≦1),
at least one of the composition ratios u and w of the first and the second fluorescent materials is different,
at least one of the composition ratios u and w of the second and the third fluorescent materials is different, and
at least one of the composition ratios u and w of the first and the third fluorescent materials is different.
